(19) United States
(12) Patent Application Publication
(10) Pub. No.: US 2005/0093154 A1
(43) Pub. Date: May 5, 2005

(54) Multiple gate semiconductor device and method for forming same

(75) Inventors: Anil Kottantharayil, Leuven (BE); Roger Loo, Kessel-Lo (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: Interuniversitair Microelektronica Centrum (IMEC vzw), Leuven (BE)

(21) Appl. No.: 10/899,659

(22) Filed: Jul. 26, 2004

Related U.S. Application Data
(60) Provisional application No. 60/492,442, filed on Jul. 25, 2003.

(30) Foreign Application Priority Data
Sep. 25, 2003 (EP) EP 03447237.3

(51) Int. Cl. H01L 23/48; H01L 21/28

(52) U.S. Cl. 257/745; 438/604

(57) ABSTRACT

In accordance with an embodiment of the invention, a FinFET device is disclosed which comprises a strained silicon channel layer formed on, at least, the sidewalls of a strain-relaxed silicon-germanium body.

### CROSS REFERENCE TO RELATED APPLICATIONS

This application claims the benefit under 35 U.S.C. § 119(e) of U.S. Provisional Patent Application No. 60/492,442, filed on Jul. 25, 2003 and under 35 U.S.C. § 119(a) of European patent application EP 03447237.3, filed on Sep. 25, 2003. U.S. Provisional Patent Application No. 60/492,442 and European patent application EP 03447237.3 are herein incorporated by reference in their entirety.

### BACKGROUND

1. Field of the Invention

This invention relates to integrated circuits and methods for manufacturing integrated circuits. More particularly, this invention relates to semiconductor devices with multiple gates that include a strained channel layer.

2. Background of the Invention

Current semiconductor chips feature technology with circuit feature sizes in the range of 130 nanometers, with components manufactured with technologies having 90 nanometer feature sizes just beginning to reach the marketplace. Industry plans are to deliver 65 nanometer technologies in the year 2007, 45 nanometer technologies in the year 2010, 32 nanometer technologies in the year 2013 and 22 nanometer technologies in the year 2016. This schedule was set forward in the International Technology Roadmap for Semiconductors (ITRS) defined by the Semiconductor Industry Association (SIA) in 2001. The schedule translates to smaller chip dimensions earlier in time than had been previously thought. Among the main transistor scaling issues to be solved is the need for thinner gate oxides that result in a higher on-current and hence increased switching speed in semiconductor devices; a smaller off-current and lower threshold voltage to allow such gate oxide scaling, and the use of lower supply voltages; a higher channel mobility; and smaller series resistance of the source/drain regions. In order to meet these forecasted stringent scaling requirements, devices other than classical Complementary Metal-Oxide-Semiconductor (CMOS) devices, as well as alternative materials, such as metal gate materials and high dielectric constant (high-k) gate dielectrics, are currently under investigation.

One non-classical CMOS device is so-called Fin Field Effect Transistors (FinFETs). In a FinFET, the gate at least partially envelops the channel region in multiple planes, as compared to a classic planar CMOS device where the gate electrode is formed in a single plane on top of the channel region, where the channel region is part of the substrate. In such a FinFET transistor, a semiconductor fin connects the source and drain regions. The gate material straddles this fin and forms, at least along the sidewalls of the fin, a gate structure (implementing one or more gates) that results in vertical channels (an in some embodiments, a horizontal channel) being defined between the source and drain, near the surface of the fin. The electrical width of a FinFET device is therefore, in a first instance, determined by the height of the fin for the vertical channels and, in a second instance, by the geometrical width of the fin for the horizontal channel. However, in such devices, decreases in carrier mobility occur due to impurity scattering resulting from doping (e.g., using in-situ doping or implantation) of the fin. Therefore, to improve the performance of such FinFET devices (e.g. by increasing the mobility of carriers in the channels) additional measures are needed.

One approach that has been employed to improve carrier mobility for devices in which holes are used as majority carriers in “planar” FinFET devices (e.g., devices using manufacturing technologies compatible with traditional CMOS manufacturing processes) is the use of a channel layer that is formed by growing silicon-germanium on silicon. An example of such an approach is described in U.S. Pat. No. 6,475,869 (the '869 patent). The '869 patent discloses a method for forming a double-gate transistor having an epitaxial silicon/germanium channel region. After forming a silicon fin having a desired width, a layer of silicon-germanium is formed on the sidewalls of the fin, and the top surface of the fin is covered with a capping layer. After forming this silicon-germanium layer, normal processing of the FinFET device is continued. While such a device configuration improves the carrier mobility for hole carriers, it is not effective for improving the carrier mobility for electron carriers, as is described in the '869 patent. Thus, techniques for improving the carrier mobility of devices employing electrons or holes as majority carriers are desirable.

### SUMMARY

An improved semiconductor device is provided. In a first embodiment, a semiconductor device includes a substrate, a first contact region and a second contact region, where the first and second contact regions are formed on the substrate. The device further includes a semiconductor fin, where the fin is in between and connects the first contact region and the second contact region. The semiconductor fin includes a strain-relaxed silicon-germanium core. This strain-relaxed silicon-germanium core has a plurality of surfaces which do not face the substrate (e.g., are orthogonal to, or are parallel with and facing away from the substrate). The device also includes a layer formed on the strain-relaxed silicon-germanium core (e.g., a strained layer). The layer formed on the strain-relaxed core may be formed from a semiconductor material including at least one element of the group III elements (of the atomic element periodic table) and at least one element of the group V elements. Alternatively, the layer may be formed using silicon and/or germanium.

In another embodiment, an improved semiconductor device includes a substrate, and a source region and a drain region formed on the substrate. The device further includes a semiconductor fin located in between, and connecting, the source region and the drain region. The device additionally includes a gate structure (which may form one or more gates) that overlies the semiconductor fin. The semiconductor fin includes, at least along its sidewalls, a layer in contact with the gate and a strain-relaxed silicon-germanium core in contact with the layer.

The layer, which is disposed in between the gate and the strain-relaxed silicon-germanium core, may be formed from a semiconductor material including at least one group III element and at least one group V element. Alternatively, the layer may be formed of silicon and/or germanium. In certain embodiments, the layer may also be present along the top surface of the semiconductor fin, in addition to being present along the sidewalls only.

A method for manufacturing an improved semiconductor device is also provided. The method includes providing a substrate on which the device is to be formed. The method further includes forming a source region, a drain region and a fin located in between, and also connecting the source region and the drain region. The fin is formed from a first semiconductor material. The source region and the drain region may be formed of the first semiconductor material or, alternatively, may be formed from one or more alternative semiconductor materials.

The method further comprises depositing an alloy layer of a second and a third semiconductor material over at least the sidewalls of the fin and at least partially oxidizing the alloy layer to form an oxide of the second material, as well as to form an alloy of the first and third semiconductor materials. The method still further includes removing the oxide layer to expose a strain-relaxed layer.

In certain embodiments, the method may further comprise depositing a layer of a fourth semiconductor material over at least the sidewalls of the fin. In such embodiments, the first and second semiconductor materials may comprise silicon. The third semiconductor material may comprise germanium, while the fourth semiconductor material may also comprise silicon. The alloy layer of the second and third semiconductor materials is selectively deposited on exposed surfaces of the fin only. The exposed surfaces may be the sidewalls and the top surface of the fin or, alternatively, only the sidewalls of the fin. The alloy comprising the first and third semiconductor materials forms a strain-relaxed body in the fin.

These and other aspects will become apparent to those of ordinary skill in the art by reading the following detailed description, with reference, where appropriate, to the accompanying drawings. Further, it should be understood that the embodiments noted in this summary are not intended to limit the scope of the invention as claimed.

### BRIEF DESCRIPTION OF THE DRAWINGS

The attached drawings are intended to illustrate some aspects and embodiments of the present invention. Devices are depicted in a simplified way for reason of clarity. Not all alternatives and options are shown and, therefore, the invention is not limited in scope by the drawings. It is noted that like reference numerals are employed to reference analogous parts of the various drawings, in which:

FIG. 1 includes FIG. 1a which is a drawing illustrating an isometric view of an improved FinFET device; FIG. 1b, which is a drawing illustrating a cross-sectional view of the FinFET of FIG. 1a along the line A-A; and FIG. 1c which is an isometric view and a cross-sectional view of another improved FinFET device that includes a fin with a Si_{1-y}Ge_{y} body;

FIGS. 2a-2e are drawings that illustrate a prior art process sequence of Ge condensation;

FIGS. 3a-3e are drawings that illustrate a process sequence for manufacturing an improved semiconductor device;

FIG. 4 is a drawing illustrating a schematic cross section along the line A-A in FIG. 3 (e.g., FIG. 3e) of the improved FinFET device illustrated in FIG. 3.

### DETAILED DESCRIPTION

While embodiments of multiple gate semiconductor devices are generally discussed herein with respect to Fin Field Effect Transistors (FinFETs), it will be appreciated that the invention is not limited in this respect and that embodiments of the invention may be implemented in any number of types of device. For example, in his article “Beyond the Conventional Transistor”, published in IBM Journal of Research & Development, Vol. 46, No. 23 2002, which in incorporated by reference herein in it entirety, H. S. Wong discloses various types of multi-gate devices. In FIGS. 14, 15 and 17 of this paper, alternative orientations of double and triple-gate devices are depicted with the corresponding process sequences being detailed on pages 146-152 of that paper. Such device configurations may be employed with embodiments of the invention.

1. Improved FinFET Devices

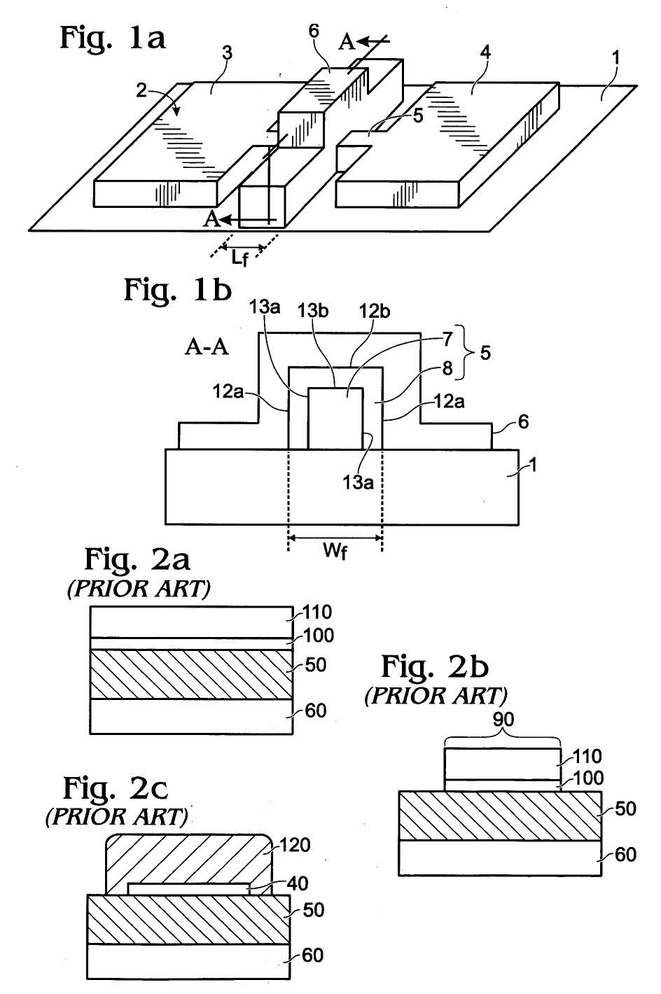

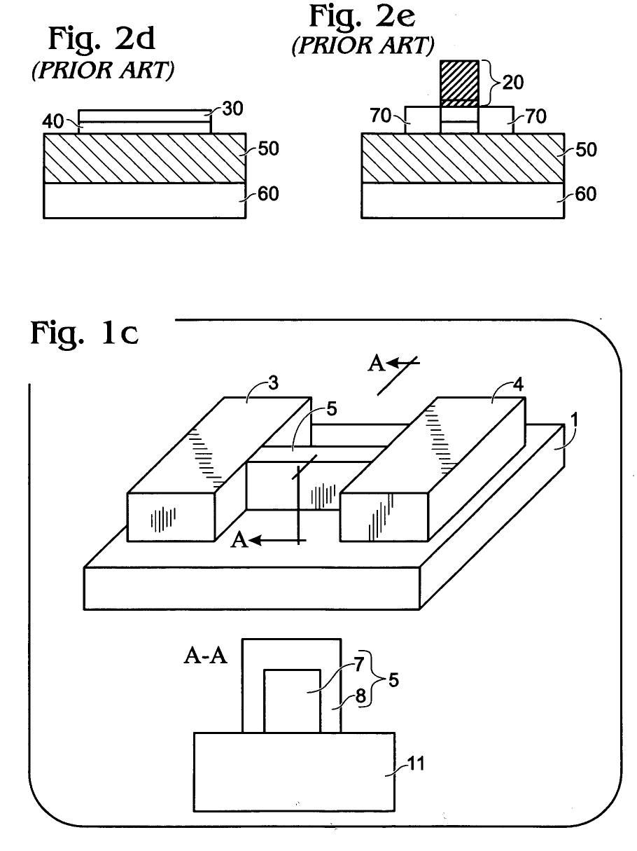

Referring now to FIG. 1, an improved semiconductor device is shown. The device of FIG. 1 may be referred to as a strained channel FinFET device. The FinFET device includes at least two gates. A fin of the FinFET includes a core of silicon-germanium and a strained silicon layer formed on the core. The FinFET of FIG. 1 further includes a gate dielectric and a gate electrode layer overlying the strained silicon layer.

FIG. 1a is a drawing illustrating an isometric view of the strained channel FinFET device. The device includes a semiconductor layer 2, which is disposed on a surface of a substrate 1. The FinFET device is formed on the surface of the substrate 1 using the layer 2. It will be appreciated that the semiconductor layer 2 may be formed over the entire surface of the substrate 1 and then patterned as shown in FIG. 1a (e.g., using photolithography and etching techniques). The substrate 1 may comprise a semiconductor substrate (e.g. silicon and/or) germanium. Alternatively, the substrate 1 may comprise an insulating layer formed on top of a semiconductor substrate to form, in combination with the semiconductor layer 2, a silicon-on-insulator (SOI) or a germanium-on-insulator (GeOI) substrate, as two examples. In certain embodiments, other semiconductor devices are formed using the semiconductor layer 2, and may be patterned concurrently with the depicted FinFET device. The other semiconductor devices would be isolated from each other and from the illustrated FinFET device using isolation techniques, such as trench, field oxide or mesa isolation.

The FinFET device of FIG. 1 includes a source region 3 and a drain region 4, which are connected by a fin 5. For the FinFET shown in FIG. 1, the source region 3, the drain region 4 and the fin 5 are formed from the semiconductor layer 2. Alternatively, the source region 3, the drain region 4 and the fin 5 may formed using two or more different layers of semiconductor material.

The FinFET device further includes a gate 6. The gate 6 is formed from a gate dielectric layer and a gate electrode layer (both of which are not specifically shown) such that the gate 6 overlies at least a portion of the fin 5 on the three sides of the fin 5 that are not facing the substrate 1. The channel(s) of the FinFET are, for this embodiment, the part of the fin 5 that is electrically influenced by the gate 6 (e.g., the part of the fin 5 that is overlaid by the gate 6).

FIG. 1b is a drawing illustrating a cross-sectional view of the FinFET device along the line A-A in FIG. 1a (e.g., along the long axis of the gate 6. The cross-sectional view shown in FIG. 1b illustrates that the gate 6 surrounds the fin 5 on surfaces 12 (sidewall surfaces 12a and top surface 12b) of the fin 5 which are not facing the substrate 1.

The FinFET of FIG. 1 may be implemented as a double-gate device or, alternatively, as a triple-gate device. To implement the FinFET as a double-gate device, the gate dielectric layer (not specifically shown) of the gate 6 on the top surface 12b of the fin 5 is thicker than the gate dielectric layer of the gate 6 along the sidewall surfaces 12a of the fin 5. In such an embodiment, inversion occurs along the vertical sidewalls 12a of the fin at a lower threshold voltage than would occur along the top surface 12b of the fin, thus creating a double-gate device.

To implement a triple-gate device, the gate dielectric layer of the gate 6 on the top surface 12b of the fin 5 is substantially the same thickness as the gate dielectric layer of the gate 6 along the sidewall surfaces 12a of the fin 5. In such an embodiment, inversion occurs along the sidewall surfaces 12a and along the top surface 12b of the fin 5 at substantially the same threshold voltage, thus creating a triple-gate device.

As may also be seen in FIG. 1b, the fin 5 of the FinFET includes a body 7 (or core) and a strained layer 8 formed on the body 7. For purposes of the discussion of FIG. 1, it will be assumed that the body 7 is silicon-germanium and the strained layer 8 is a strained silicon layer.

In order to obtain the strained silicon layer 8 with desirable characteristics, the underlying silicon-germanium body 7 has substantially uniform lattice characteristics along surfaces 13 (sidewall surfaces 13a and top surface 13b) upon which the strained silicon 8 layer is formed. At substantially every point along the surfaces 13, the composition of the lattice of the body 7 in a direction perpendicular to the surfaces 13 will be substantially the same.

Depending on the particular embodiment, it may be desirable that the lattice constant of the body 7 be substantially the same as the lattice constant of a bulk relaxed silicon-germanium layer having the same given germanium content, such that the body 7 is substantially completely relaxed. In such an embodiment, the body 7 may be implemented as a crystalline, strain-relaxed layer (e.g., a strain-relaxed silicon-germanium layer).

The semiconductor body 7 has a width=W_{f} and a channel length=L_{f}. The channel length is approximately the distance that the gate 6 overlies the fin 5 in a direction perpendicular to the line A-A in FIG. 1b, as shown. The channel length L_{f} may be 100 nm (nanometers) or less, 50 nm or less, or 25 nm or less. For embodiments where the strain-relaxed core 7 is formed of an alloy of semiconductor materials (e.g. silicon alloyed with germanium) the percentage content of each alloying element will depend on the particular embodiment (e.g., on the type of majority carriers employed and/or the material used for the strained layer 8).

The strained layer 8 (e.g., a crystalline layer, such as silicon) is formed over at least a part of the exposed surface of the strain relaxed core 7. If the strained layer 8 is to be formed from silicon on a strain-relaxed silicon-germanium core 7, then up to 50%, or up to 35% or up to 15% of germanium should present in the core. If the strained layer 8 is to be formed from germanium on a strain-relaxed silicon-germanium core 7, then it is desirable that the core 7 contain more than 60% germanium. The desired germanium content in the core 7 depends, at least in part, on the type of carriers employed in the FinFET. For example, for FinFETs that employ electrons as the majority carrier, the germanium content in the core 7 may be in the range of 5-20%, while the germanium content for FinFETs that employ holes as majority carriers may be 25% or more.

Referring to FIG. 1c, another embodiment of an improved semiconductor device is shown. The device of FIG. 1c includes a first semiconductor contact region 3, a second semiconductor contact region 4 and a semiconductor fin 5 in between and connecting the first contact region 3 and the second contact region 4, as is shown in FIG. 1c. This device is formed on a substrate 1, as the device of FIG. 1a. However, for the device shown in FIG. 1c, the first contact region 3 and the second contact region 4 are formed of the same semiconductor material, e.g. silicon, while the body or core 7 of the semiconductor fin 5 is formed of a different material than the contract regions 3 and 4, such as silicon-germanium Si_{1-y}Ge_{y}, where 0<y<100%. Again, it is desirable that the silicon-germanium of the body 7 is crystalline and strain-relaxed.

A semiconductor layer 8 is grown (or deposited) on the exposed surfaces of this body 7. Depending on the lattice constant mismatch between the layer 8 and the body 7, compressive strain, tensile strain or no strain may be present in the layer 8. If the layer 8 is a germanium layer grown on a silicon-germanium body 7, then the germanium layer 8 will be strained depending on the germanium content of the body 7 (e.g., the more germanium content in the body 7 the less strain will be present in the layer 8).

Alternatively, the layer 8 may be formed on the silicon-germanium body 7 using other semiconductor layer compositions. For example, the semiconductor material of the layer 8 may be a material that includes at least one group III element and at least one group V element (of the periodic table of atomic elements), such as AlAs, GaAs, and AlGaAs, which are commonly used in optoelectronic devices. By adjusting the germanium content in the body 7, the lattice constant of the body 7 may be adjusted such that a small lattice mismatch with the layer 8 is realized. In such a situation, a layer 8 with low or no strain may be produced. Such an embodiment would, among other things, provide for the formation of, and integration of, optoelectronic devices in CMOS technologies, as such FinFET devices could be combined with optical devices.

2. Method of Manufacturing an Improved FinFET Device

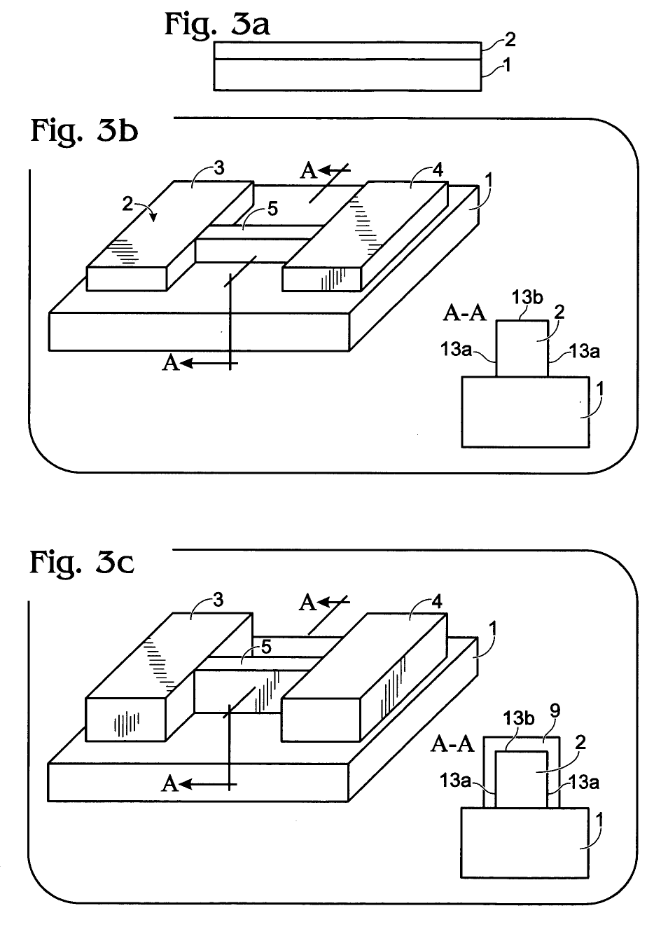

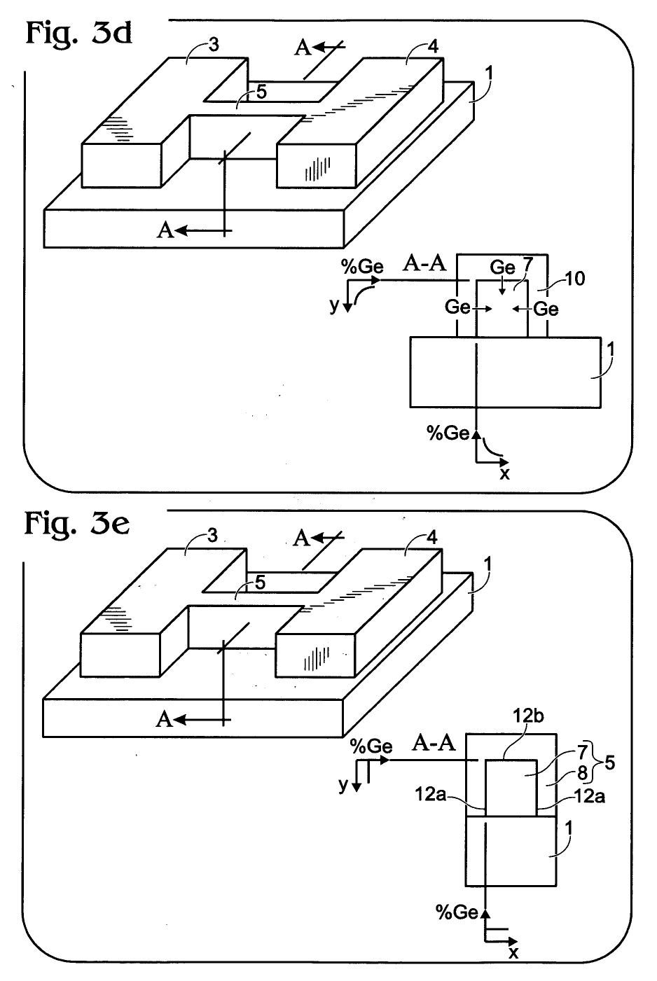

Referring to FIGS. 3a-3e, a method for manufacturing a strained channel FinFET device having at least two gates includes forming a source region, a drain region and a fin, where the fin is in between and connects the source region and the drain region. The source region, the drain region and the fin may be formed of the same semiconductor material or may be formed from different semiconductor materials. In this embodiment, the fin of the FinFET includes a body of SiGe and a strained silicon layer covering at least the sidewalls of the body. The method further includes forming a gate dielectric layer and a gate electrode layers that overlay the strained silicon layer.

Published U.S. Patent Application No. 2003/0006461 discloses a method for forming a planar CMOS device within a region of strain-relaxed silicon-germanium (SiₓGe_{y}). U.S. Application No. 2003/0006461 is hereby incorporated by reference in its entirety. This application describes forming a planar strained silicon layer on top of a planar region of strain-relaxed silicon-germanium. The formation of the strain-relaxed region is illustrated by FIGS. 2a-2e (which correspond to FIGS. 8A-8E of US 2003/0006461).

The process for forming such a device comprises the formation of a stack that includes a SiGe layer 110 and a Si layer 100. The stack is formed on an oxide layer 50, which is formed on a substrate 60. This stack of layers 100 and 110 is patterned to form an array of islands 90 of limited diameter (e.g. 5 micrometers). After this patterning, a dry oxidation process is performed to oxidize the exposed parts of the patterned SiGe layer 100. During this oxidation process, Ge atoms are expelled from the forming silicon oxide surface layer 120 into the remaining, i.e. un-oxidized, SiGe layer 110.

By inter-diffusion of the piled-up Ge atoms and the Si atoms (also originating from the underlying patterned Si layer 100), the profile of the Ge in the resulting semiconductor layer 40 will be flat and is constant in a direction perpendicular to the substrate 60 on which the stack of the SiGe layer 110 on the Si layer 100 was formed. The formed silicon-oxide layer 120 is then removed. The removal of the silicon-oxide layer leaves a lattice relaxed planar buffer layer 40 on which a planar strained silicon layer 30 is formed. This method sequence, which is known as “germanium condensation” has only been applied to such planar structures.

After formation of the strained silicon layer 30, as is shown in FIG. 2e, a gate stack 20 (including a gate dielectric layer and a gate electrode layer) of the planar device is formed on top of the strained silicon layer 30. As is also shown in FIG. 2e, source/drain regions 70 are formed in each island 90 (e.g. using ion implantation at opposite sides of the gate stack 20). Thus, U.S. Patent Application 2003/0006461 it directed to forming a planar device that includes a strain-relaxed buffer layer where the entire active area of the device (the drain, source and channel) is formed in a strained planar layer.

More generally, the germanium condensation technique can be described as forming an alloy layer of a second and third semiconductor material over a first semiconductor layer or structure. During oxidation of the alloy layer, the atoms of the third semiconductor material are expelled and form another alloy with the underlying first semiconductor layer. Hence both of the first and third semiconductor materials must be miscible, while the solubility of the third semiconductor material with the oxide of the first semiconductor layer should be low or negligible. The newly formed alloy of the first and third semiconductor materials yields a strain-relaxed layer by performing an annealing step. A layer of a fourth semiconductor material, with a different lattice constant than the lattice constant of the alloy of first and third semiconductor materials, is then formed over the alloy to yield a strained layer over the strain-relaxed layer.

The first, second, third and fourth semiconductor layers may be selected from the atomic groups III, IV or V. Further, the first, second, third and fourth semiconductor layers may be selected from the group of elements Si, Ge, and C. Still further, the fourth semiconductor layer may be GaAs, AlAs or AlGaAs.

Referring again to FIG. 1c, a layer 8 of a fourth semiconductor material or an alloy including the fourth semiconductor material is grown with or without strain on the alloy of the first and third semiconductor materials. Depending on the mismatch between the lattice constant of the layer 8 and the lattice constant of the alloy of the first and third semiconductor materials (which may form the body 7 in FIG. 1c), compressive, tensile or no strain may be present in the layer 8. If silicon is used to form the layer 8 and the layer 8 is grown on a silicon-germanium body 7, then the silicon layer 8 will be strained. If germanium is used to form the layer 8 and is grown on a silicon-germanium body 7, the germanium layer 8 will be strained depending on the germanium content (e.g., the more germanium content in the body 7 the lower the strain in the layer 8).

Of course other types of semiconductor layers may be formed on such a silicon-germanium body 7. For example, the fourth semiconductor material may be a semiconductor material that includes at least one group III element and at least one group V element, such as AlAs, GaAs, and AlGaAs. By adjusting the germanium content of the body 7, a small lattice mismatch with the layer 8 may be realized. This combination of an overlay layer 8 and a strain-relaxed body 7 with low lattice mismatch would, among other things, allow the formation of, and integration of, optoelectronic components in CMOS technologies, as FinFET devices may be combined with optical devices, as was previously described.

In an alternative method for manufacturing an improved FinFET device, the “germanium condensation technique” is used to form a FinFET device that includes a strain-relaxed semiconductor lattice (e.g. a strain-relaxed SiGe lattice). The strain-relaxed lattice has substantially uniform characteristics on its exposed sides. FIGS. 3a-e are drawings that illustrate a method for manufacturing such a FinFET device. As was described with respect to FIG. 1, a semiconductor layer 2 is grown (e.g., deposited) on a substrate 1, as may be seen in FIG. 3a. As was previously described, the substrate 1 may be a semiconductor substrate or may be an insulator layer formed on a semiconductor substrate. The layer 2 is a material in which the active areas of a FinFET device will be formed. Of course, the active areas may also be formed from multiple semiconductor materials, as was previously described.

Referring now to FIG. 3b, a source region 3, a drain region 4 and a fin 5 are formed from the semiconductor layer 2. In the cross-sectional view along line A-A in FIG. 3b, it may be seen that the surfaces 13 (the sidewall surfaces 13a and the top surface 13b) of the fin 5 are those surface which do not face the substrate 1 (e.g., are perpendicular to, or are parallel to and facing away from, the substrate 1).

In FIGS. 3a-e, only the top oxide layer of a SOI substrate will be shown and, as noted above, the source region 3, the drain region 4 and the fin 5 are formed from the same semiconductor layer 2. Patterning steps (e.g., photolithography and etching techniques) are performed to define the source region 3, the drain region 4 and the fin 5 in the semiconductor layer 2. As may be seen in FIG. 3b, the fin 5 is located in between and connects the source region 3 and the drain region 4.

A characteristic of the FinFET device of FIG. 3 is that the width W_{f} of the fin is independent of the width of the source region 3 and the drain region 4. In comparison, for a planar device, the width of a transistor is defined by the width of the active area. In such devices the width of the channel region equals the width of the adjacent source and drain regions. In the case of a FinFET, however, the fin is typically smaller than the source region and the drain region and multiple fins are often formed in between the source region 3 and the drain region 4. While the area of the source region 3 and the drain region 4 are made large enough to allow the formation of contact holes on top of them that connect the source region 3 and the drain region 4 with other interconnect levels, the width of the fin(s) 5 is selected to improve the channel performance and, thus, the performance of the FinFET. For FinFETs such as the FinFET illustrated in FIG. 3, where the fin 5, the source region 3 and the drain region 4 are to be formed from the same semiconductor layer 2, the source region 3 and the drain 4 region is defined using a first exposure step (e.g., using optical lithography), while the smaller fin 5 is defined using a second exposure step (e.g., using an electron beam). Both exposure patterns are then etched during the same etching step (e.g., using a dry etching process). The etching step transfers the exposure patterns to the semiconductor layer 2. Using such techniques, a FinFET with a fin width W_{f} of 100 nm or less may be constructed.

For the method illustrated in FIG. 3, after patterning the semiconductor layer 2 to form the source region 3, the drain region 4 and the fin 5 of the FinFET device, a uniform and conformal SiGe layer 9 is deposited. As shown in FIG. 3c, the layer 9 is formed selectively on the patterned semiconductor layer 2, while SiGe is not deposited on the exposed portions of the substrate 1. Such selective deposition may be obtained by using selective epitaxial growth. Alternatively, the SiGe layer 9 may be formed only on the source region 3, the drain region 4 and the fin 5 using selective atomic layer deposition (ALD). As may seen in the cross-sectional view along line A-A of FIG. 3c, the fin 5 has a rectangular cross-section with sidewall surfaces 13a perpendicular to the substrate 1 and a top surface 13b parallel to and facing away from the substrate 1. The surfaces 13a and 13b of the fin 5 are covered with the SiGe layer 9.

As an alternative to using selective deposition techniques, the substrate on which the FinFET is being manufactured (e.g., the substrate 1, the source region 3, the drain region 4 and the fin 5) may be covered uniformly with a SiGe layer 9. In this situation, the SiGe layer 9 covering the exposed surfaces of the substrate 1 around the FinFET must be removed (e.g., using photolithography and etching techniques) or modified in order to avoid short-circuiting the device with other devices (e.g., for embodiments where multiple fins 5 are formed). For example, the SiGe layer 9 may be substantially completely oxidized during the germanium condensation process, thus forming an insulating layer between, for example, multiple FinFET devices. The Ge in the SiGe layer 9 covering the exposed surfaces of the substrate 1 will be removed during the etching of the oxide layer due to the volatility of germanium.

For purposes of the discussion of FIG. 3, it will be assumed that local deposition techniques are used to form the SiGe layer 9. After the SiGe layer 9 is deposited, the substrate on which the FinFET is being manufactured is placed in an oxidizing atmosphere, where the SiGe layer 9 is substantially uniformly oxidized over it surface. The SiGe layer 9 will, as a result, be at least partially oxidized. As a result, a silicon-oxide layer 10 is formed on top of the SiGe layer 9, which at least partially reduces the thickness of the SiGe layer 9, as is shown in the cross-sectional view along line A-A in FIG. 3d.

Because the SiGe layer 9 is uniformly formed, and the SiGe layer 9 is oxidized in a substantially uniform fashion, Ge atoms diffuse from the outer surface of the SiGe layer 9 towards the center of the fin 5, as is indicated by the arrows labeled Ge in the cross-sectional view of FIG. 3d. This is also graphically shown in FIG. 3d by Ge concentration profiles in the horizontal direction (e.g., parallel to the substrate 1) and in the vertical direction (perpendicular to the substrate 1). These profiles indicate an initial pile-up of Ge atoms at the interface of an oxide layer 10 (formed as a result of the oxidation of the SiGe layer 9) and the SiGe layer 9). It is noted that the SiGe layer 9 is not specifically indicated in FIG. 3d.

However, after the initial pile up of Ge atoms at the interface of the layer 10 and the SiGe layer 9, substantially the same Ge profile will be obtained after the oxidation process is complete. This constant Ge concentration profile is the result of inter-diffusion of the piled-up Ge atoms and the Si atoms. It will be appreciated that Si atoms also originate from the underlying layer 2 (as shown in FIG. 3b). The profile of Ge in the resulting semiconductor layer (the body 7) is constant, as is shown FIG. 3e by the dopant profiles in vertical and horizontal direction indicated at the cross-sectional view. The oxide layer 10 is removed by an etching step (e.g. a wet etch process using HF-based chemistry) or an in-situ plasma cleaning performed in a deposition chamber, leaving a newly formed strain-relaxed SiGe layer 7 exposed (which forms the body of the fin for the FinFET. While the as-deposited silicon fin 5 (formed from silicon layer 2) will typically be substantially completely converted into the strain-relaxed SiGe layer 7, the source region 3 and the drain region 4 will, due to their larger dimensions, only be partially converted to SiGe (e.g., the region near the exposed surfaces of source region 3 and the drain region 4 is converted into SiGe leaving the composition of the center of source and drain as-deposited, in this case Si).

It is noted that the exemplary method offers the advantage of subjecting the deposited SiGe layer to a limited number of processing steps, which is desirable due to the volatility of germanium and the propensity of SiGe to oxidize due to this volatility. In situations where the conformal SiGe layer 9 of the fin will only be partially oxidized, some part of the layer 9 will remain in the final strain-relaxed SiGe layer 7. Therefore, it is desirable that a crystalline SiGe layer 9 be formed, as is typically accomplished using selective epitaxial layer growth. If, however, the conformal SiGe layer 9 is to be substantially completely oxidized, the crystal structure of the as-deposited SiGe layer 9 is of little importance and other conformal deposition techniques can be used, such as non-selective epitaxial growth or chemical vapor deposition (CVD), which would yield a polycrystalline SiGe layer 9 on the oxide of the underlying substrate 1.

Referring now to the FIG. 3e, after the removal of the oxide layer 10 (as shown in FIG. 3d) a strained silicon layer 8 is formed over the exposed strain-relaxed SiGe layer 7. The strained silicon layer 8 encapsulates the underlying strain-relaxed SiGe layer 7. As is shown in the cross-sectional view in FIG. 3e (along line A-A), the fin 5 has a rectangular cross-section with sidewall surfaces 12a perpendicular to the substrate 1 and a top surface 12b parallel to the substrate 1, which is not facing the substrate 1. The surfaces 12 are covered with the strained-silicon layer 8.

The processing of the FinFET of FIG. 3 is then continued. This further processing includes forming a gate on top of the strained silicon layer 7, where the gate includes a gate dielectric and a gate electrode. The gate is formed is formed by the deposition and patterning of dielectric and conductive layers. The source region 3 and the drain region 4 are implanted. This implant is also used to dope the gate for embodiments where a semiconductor material, such as polysilicon, is used to form the gate electrode layer. Other process steps, such as forming insulating layers covering the FinFET device, forming electrical contacts to contact the source region 3, the drain region 4 and the gate of the device, are then executed to complete processing of the FinFET device.

3. FinFET Capping Layer

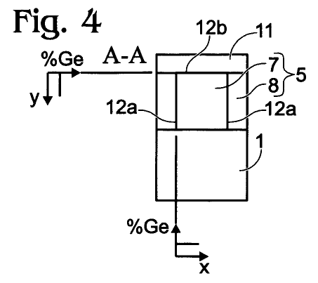

Referring now to FIG. 4, with additional reference to FIG. 3, a capping layer 11 is illustrated that may be used in certain embodiments to protect the top surface of the fin 5. The capping layer 11 may be deposited uniformly over the semiconductor layer 2 and patterned together with the active layer 2 during the patterning of the fin. As the capping layer 11 effectively adds to the thickness of the gate dielectric layer when formed on top of the fin 5, a double-gate FinFET is formed in such embodiments. Further, for such embodiments, the Ge content of the as-deposited SiGe layer 9 will, during the oxidation step, only diffuse into the sidewall surfaces 12a of the underlying as-deposited body 7 (formed from the layer 2), as the capping layer 11 acts as a diffusion barrier layer along the top surface 12a of the fin 5. A strained silicon layer 8 is thus formed on the SiGe body 7 sidewall surfaces 12a. The SiGe layer 9 and/or the strained-silicon layer 8 are typically formed in a uniform way, as was discussed above.

FIG. 4 is a cross-section of such a device showing the device after the strained silicon layer 8 has been selectively formed on the SiGe body 7. As is shown in the cross-sectional view of FIG. 4 (such as along the line A-A in FIG. 3) the fin 5 has a rectangular cross-section with sidewall surfaces 12a perpendicular to the substrate 1 and a top surface 12b parallel to the substrate 1. Only the sidewall surfaces 12a are covered with the strained-silicon layer 8.

### 6. Conclusion

Various arrangements and embodiments in accordance with the present invention have been described herein. It will be appreciated, however, that those skilled in the art will understand that changes and modifications may be made to these arrangements and embodiments without departing from the true scope and spirit of the present invention, which is defined by the following claims.

1. A semiconductor device comprising:
a substrate;
a first contact region and a second contact region formed on the substrate;
a semiconductor fin in between and connecting the first contact region and the second contact region, the semiconductor fin having a body comprising a strain-relaxed material, the body having a surface, the surface not facing the substrate.

2. The semiconductor device of claim 1 wherein the strain-relaxed material is an Si_{1-y}Ge_{y} alloy with 0<y<1.

3. The semiconductor device of claim 2 further comprising a layer, the layer at least partially overlapping the body, and the layer being lattice mismatched with the underlying strain-relaxed body.

4. The semiconductor device of claim 3 wherein the overlapping layer at least covers those parts of the surface of the body, which are oblique to the substrate.

5. The semiconductor device of claim 3 wherein the overlapping layer covers substantially the entire surface.

6. The semiconductor device of claim 3 further comprising a gate, which at least partially, straddles the semiconductor fin.

7. The semiconductor device of claim 6 wherein the first contact region is a source region and the second contact region is a drain region of a Field Effect Transistor.

8. The semiconductor device of claim 3 wherein the layer comprises one or more elements selected from the atomic groups III, IV or V.

9. The semiconductor device of claim 8, wherein one of the elements is germanium.

10. The semiconductor device of claim 8, wherein one of the elements is silicon.

11. The semiconductor device of claim 8, wherein the layer comprises AlAs, GaAs or AlGaAs.

12. The semiconductor device of claim 1 further comprising a layer, the layer at least partially overlapping the body, and the layer being lattice mismatched with the underlying strain-relaxed body.

13. A method for manufacturing a semiconductor device having a fin, the fin comprising a strain-relaxed body, comprising:
providing a substrate, wherein the substrate comprises a source, a drain, and a fin in between, and connecting, the source and the drain, the fin having a body being formed of a first semiconductor material; the fin having a surface not facing the substrate,
depositing, at least on those parts of the surface which are oblique to the substrate, an alloy layer comprising a second and a third semiconductor material;
at least partially oxidizing the alloy layer thereby forming an oxide of the second material and thereby converting the body of a first semiconductor material in to an alloy of the first and the third semiconductor materials, the alloy being a strain-relaxed material; and
removing the oxide of the second semiconductor material.

14. The method of claim 13 further comprising the step of forming a layer comprising a fourth semiconductor material, the layer at least partially overlaying the body, and the layer being lattice mismatched with the underlying strain-relaxed body.

15. The method of claim 14 wherein
the layer at least covers those parts of the surface which are oblique to the substrate.

16. The method of claim 14 wherein the first and/or the second semiconductor materials comprise silicon.

17. The method of claim 14 wherein the third semiconductor material comprises germanium.

18. The method of claim 14 wherein the fourth semiconductor material is selected from the atomic groups III, IV or V.

19. The method of claim 18 wherein the fourth semiconductor material comprises silicon.
